(19) United States
(12) Patent Application Publication
(10) Pub. No.: US 2025/0129474 A1
(43) Pub. Date: Apr. 24, 2025

(54) SUBSTRATE PROCESSING METHOD AND SUBSTRATE PROCESSING APPARATUS

(71) Applicant: Tokyo Electron Limited, Tokyo (JP)

(72) Inventors: Ryota IFUKU, Nirasaki-shi (JP); Masataka TOIYA, Nirasaki-shi (JP); Eiki KAMATA, Nirasaki-shi (JP); Hiroki YAMADA, Nirasaki-shi (JP); Takashi MATSUMOTO, Nirasaki-shi (JP)

(21) Appl. No.: 18/999,454

(22) Filed: Dec. 23, 2024

Related U.S. Application Data
(63) Continuation of application No. PCT/JP2023/022199, filed on Jun. 15, 2023.

(30) Foreign Application Priority Data
Jun. 29, 2022 (JP) 2022-104162

(51) Int. Cl. C23C 16/455; H01J 37/32; H01L 21/02

(52) U.S. Cl. CPC C23C 16/45557; H01L 21/02115; H01L 21/02274; H01J 37/32311; H01J 2237/3321

(57) ABSTRACT

A method of processing a substrate includes placing the substrate on a stage in a process container, supplying a plasma generating gas into the process container to generate plasma of first power at a first pressure, controlling an inside of the process container to a second pressure lower than the first pressure, and supplying a carbon-containing gas into the process container to form a graphene film on the substrate.

### CROSS-REFERENCE TO RELATED APPLICATION

This application is a bypass continuation application of international application No. PCT/JP2023/022199, having an international filing date of Jun. 15, 2023, and designating the United States, the international application being based upon and claiming the benefit of priority from Japanese Patent Application No. 2022-104162, filed on Jun. 29, 2022, the entire contents of each of which are incorporated herein by reference.

### TECHNICAL FIELD

The present disclosure relates to a substrate processing method and a substrate processing apparatus.

### BACKGROUND

In recent years, graphene films have been proposed as a new thin film barrier layer material to replace metal nitride films. In graphene film formation techniques, for example, a microwave plasma CVD (Chemical Vapor Deposition) device is used to form a graphene film directly on a silicon substrate, an insulating film, or the like by performing graphene film formation at a high radical density/low electron temperature (see, e.g., Patent Document 1).

### PRIOR ART DOCUMENTS

### Patent Documents

Patent Document 1: Japanese Patent Application Publication No. 2019-055887
Patent Document 2: Japanese Patent Application Publication No. 2020-147839
Patent Document 3: Japanese Patent Application Publication No. 2021-031706
Patent Document 4: Japanese Patent Application Publication No. 2021-088735

### SUMMARY

According to one embodiment of the present disclosure, there is provided a method of processing a substrate includes placing the substrate on a stage in a process container, supplying a plasma generating gas into the process container to generate plasma of first power at a first pressure, controlling an inside of the process container to a second pressure lower than the first pressure, and supplying a carbon-containing gas into the process container to form a graphene film on the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a film forming apparatus in an embodiment of the present disclosure.

FIG. 2 are graphs showing examples of changes in electron density during plasma ignition and pressure control.

FIG. 3 are graphs showing examples of changes in electron temperature during plasma ignition and pressure control.

FIG. 4 is a diagram showing an example of a peak evaluating method in an electron density graph.

FIG. 5 is a diagram showing an example of an evaluation value of an electron temperature for combinations of supply power and pressure during plasma ignition.

FIG. 6 are diagrams showing examples of evaluating a pressure control method and a carbon-containing gas supply method.

FIG. 7 is a flowchart showing an example of a film forming process in the present embodiment.

FIG. 8 are diagrams showing examples of experimental results in a reference example and the present embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the following, embodiments of a substrate processing method and a substrate processing apparatus will be described in detail with reference to the drawings. The disclosed techniques are not limited to the following embodiments.

In graphene film formation, for example, using a microwave plasma CVD apparatus, a single-wafer film forming process of repeating graphene film formation and dry cleaning of a chamber with oxygen without using a pre-coat is given as an example of a process sequence. In this process sequence, particles may increase irregularly. On the other hand, the graphene film formation is generally performed in a low pressure zone where microwave plasma is difficult to ignite. For this reason, a sequence in which plasma is ignited at a high pressure and then reduced to a low pressure is used in the graphene film formation. However, it may be considered that a transient state at the time of such plasma ignition induces the generation of unexpected particles. Therefore, it is expected that the unexpected generation of particles can be suppressed.

### Configuration of Film Forming Apparatus 1

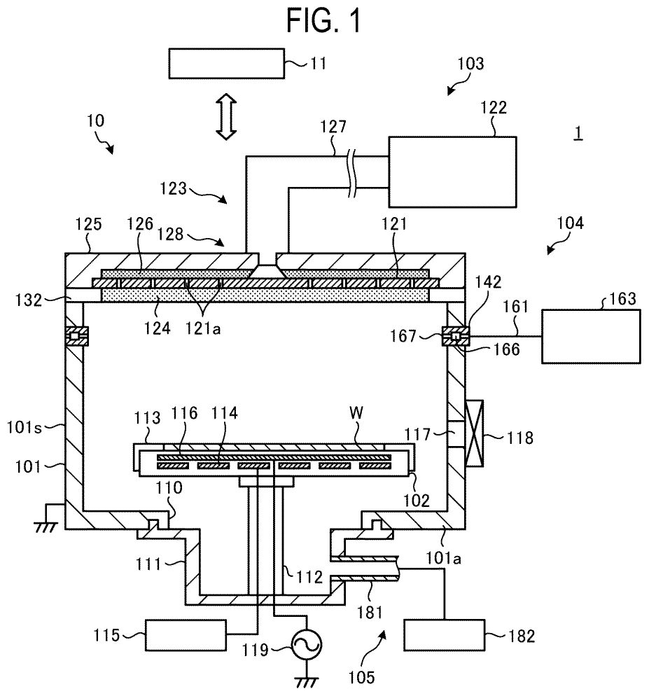

FIG. 1 is a schematic cross-sectional view showing an example of a film forming apparatus in an embodiment of the present disclosure. The film forming apparatus 1 illustrated in FIG. 1 is configured as, for example, a plasma processing apparatus of the RLSA (registered trademark) microwave plasma type. The film forming apparatus 1 is an example of a substrate processing apparatus.

The film forming apparatus 1 includes an apparatus body 10 and a controller 11 that controls the apparatus body 10. The apparatus body 10 includes a chamber 101, a stage 102, a microwave introducer 103, a gas supply 104, and an exhauster 105.

The chamber 101 is formed in a substantially cylindrical shape, and an opening 110 is formed in the substantially central portion of a bottom wall 101a of the chamber 101. The bottom wall 101a is provided with an exhaust chamber 111 that communicates with the opening 110 and protrudes downward. An opening 117 through which a substrate (hereinafter also referred to as a wafer) W passes is formed in a side wall 101s of the chamber 101, and the opening 117 is opened/closed by a gate valve 118. The chamber 101 is an example of a process container.

The substrate W to be processed is placed on the stage 102. The stage 102 is substantially disc-shaped and made of ceramics such as AlN. The stage 102 is supported by a cylindrical support member 112 made of ceramics such as AlN, which extends upward from the approximate center of the bottom of the exhaust chamber 111. An edge ring 113 is provided on the outer edge of the stage 102 so as to surround the substrate W placed on the stage 102. Further, lift pins (not shown) for raising/lowering the substrate W are provided inside the stage 102 so as to be able to be protruded/retracted from the upper surface of the stage 102.

Furthermore, a resistance heating type heater 114 is embedded inside the stage 102, and the heater 114 heats the substrate W placed on the stage 102 according to power supplied from a heater power supply 115. In addition, a thermocouple (not shown) is disposed inside the stage 102, and the temperature of the substrate W can be controlled to a range of, for example, 350 to 850 degrees C. based on a signal from the thermocouple. In addition, an electrode 116 having approximately the same size as the substrate W is buried above the heater 114 in the stage 102, and a bias power supply 119 is electrically connected to the electrode 116. The bias power supply 119 supplies bias power of a predetermined frequency and magnitude to the electrode 116. The bias power supplied to the electrode 116 attracts ions to the substrate W placed on the stage 102. The bias power supply 119 may not be provided depending on the characteristics of the plasma processing.

The microwave introducer 103 is provided at the top of the chamber 101 and includes an antenna 121, a microwave output part 122, and a microwave transmitter 123. The antenna 121 has a number of slots 121a that are through-holes. The microwave output part 122 outputs a microwave. The microwave transmitter 123 guides the microwave output from the microwave output part 122 to the antenna 121.

A dielectric window 124 made of a dielectric material is provided below the antenna 121. The dielectric window 124 is supported by a support member 132 that is provided in a ring shape at the top of the chamber 101. A slow-wave plate 126 is provided above the antenna 121. A shield member 125 is provided above the antenna 121. A flow path (not shown) is provided inside the shield member 125, and the shield member 125 cools the antenna 121, the dielectric window 124, and the slow-wave plate 126 with a fluid such as water flowing through the flow path.

The antenna 121 is formed of, for example, a copper plate or aluminum plate whose surface is plated with silver or gold, and has a plurality of slots 121a for radiating a microwave which is arranged in a predetermined pattern. The arrangement pattern of the slots 121a is appropriately set so that the microwave is radiated evenly. An example of a suitable pattern may include a radial line slot in which a plurality of pairs of slots 121a are arranged concentrically, with two slots 121a arranged in a T-shape as one pair. The length and arrangement interval of the slots 121a are appropriately determined according to the effective wavelength (λg) of the microwave. The slots 121a may also have other shapes such as a circular shape and an arc shape. Furthermore, the arrangement form of the slots 121a is not particularly limited, and they may be arranged in a concentric shape, for example, a spiral shape or a radial shape. The pattern of the slots 121a is appropriately set so as to obtain microwave radiation characteristics that provide a desired plasma density distribution.

The slow-wave plate 126 is made of a dielectric material having a dielectric constant greater than that of a vacuum, such as quartz, ceramics (Al₂O₃), polytetrafluoroethylene, or polyimide. The slow-wave plate 126 has a function of making the wavelength of the microwave shorter than that in the vacuum, thereby making the antenna 121 smaller. The dielectric window 124 is also made of a similar dielectric material.

The thicknesses of the dielectric window 124 and the slow-wave plate 126 are adjusted so that an equivalent circuit formed by the slow-wave plate 126, the antenna 121, the dielectric window 124, and the plasma satisfies a resonance condition. By adjusting the thickness of the slow-wave plate 126, the phase of the microwave can be adjusted. By adjusting the thickness of the slow-wave plate 126 so that the joint of the antenna 121 becomes the “antinode” of a standing wave, the reflection of the microwave can be minimized so that the radiation energy of the microwave can be maximized. In addition, by using the same material for the slow-wave plate 126 and the dielectric window 124, the interface reflection of the microwave can be prevented.

The microwave output part 122 has a microwave oscillator. The microwave oscillator may be of a magnetron type or a solid-state type. The frequency of a microwave generated by the microwave oscillator is, for example, a frequency of 300 MHz to 10 GHz. As an example, the microwave output part 122 outputs a microwave of 2.45 GHz by a magnetron type microwave oscillator. The microwave is an example of an electromagnetic wave.

The microwave transmitter 123 has a waveguide 127 and a coaxial waveguide 128. It may further have a mode converter. The waveguide 127 guides the microwave output from the microwave output part 122. The coaxial waveguide 128 includes an inner conductor connected to the center of the antenna 121 and an outer conductor on the outside thereof. The mode converter is provided between the waveguide 127 and the coaxial waveguide 128. The microwave output from the microwave output part 122 propagates through the waveguide 127 in a TE mode and is converted from the TE mode to a TEM mode by the mode converter. The microwave converted to the TEM mode propagates to the slow wave plate 126 via the coaxial waveguide 128 and is radiated from the slow wave plate 126 into the chamber 101 via the slots 121a of the antenna 121 and the dielectric window 124. In addition, a tuner (not shown) for matching the impedance of a load (plasma) in the chamber 101 to the output impedance of the microwave output part 122 is provided in the middle of the waveguide 127.

The gas supply 104 has a shower ring 142 provided in a ring shape along the inner wall of the chamber 101. The shower ring 142 has a ring-shaped flow path 166 provided therein and a number of discharge ports 167 that are connected to the flow path 166 and open to the inside. A gas supplier 163 is connected to the flow path 166 via a pipe 161. The gas supplier 163 is provided with a plurality of gas sources and a plurality of flow rate controllers. In one embodiment, the gas supplier 163 is configured to supply at least one process gas from a corresponding gas source to the shower ring 142 via a corresponding flow rate controller. The gas supplied to the shower ring 142 is supplied into the chamber 101 from a plurality of discharge ports 167.

When a graphene film is formed on the substrate W, the gas supplier 163 supplies a carbon-containing gas, a hydrogen-containing gas, and a rare gas, each of which is controlled to a predetermined flow rate, into the chamber 101 via the shower ring 142. In this embodiment, the carbon-containing gas is, for example, an acetylene (C₂H₂) gas. In addition to the acetylene (C₂H₂) gas, any of an ethylene (C₂H₄) gas, a methane (CH₄) gas, an ethane (C₂H₆) gas, a propane (C₃H₈) gas, a propylene (C₃H₆) gas, a methanol (CH₃OH) gas, and an ethanol (C₂H₅OH) gas may be used. In this embodiment, the hydrogen-containing gas is, for example, a hydrogen gas. Instead of or in addition to the hydrogen gas, a halogen-based gas such as a F₂ (fluorine) gas, a Cl₂ (chlorine) gas, or a Br₂ (bromine) gas may be used. In this embodiment, the rare gas is, for example, an Ar gas. Instead of the Ar gas, another rare gas such as a He gas may be used.

The exhauster 105 has an exhaust chamber 111, an exhaust pipe 181 provided on the side wall of the exhaust chamber 111, and an exhaust device 182 connected to the exhaust pipe 181. The exhaust device 182 has a vacuum pump, a pressure control valve, and the like.

The controller 11 has a memory, a processor, and an input/output interface. The memory, which is a non-transitory computer readable storage medium, stores a program executed by the processor and a recipe including conditions for each process. The processor executes the program read from the memory and controls each part of the apparatus body 10 via the input/output interface based on the recipe stored in the memory.

For example, the controller 11 controls each part of the film forming apparatus 1 to perform a film forming method to be described later. In a detailed example, the controller 11 executes a process of placing the substrate W on the stage (mounting table) 102 in the chamber 101. The controller 11 executes a process of supplying a plasma generating gas into the chamber 101 to generate plasma with first power at a first pressure. The controller 11 executes a process of controlling the internal pressure of the chamber 101 to a second pressure lower than the first pressure. The controller 11 executes a process of supplying a carbon-containing gas into the chamber 101 to form a graphene film on the substrate W. Here, the carbon-containing gas may be an acetylene (C₂H₂) gas supplied from the gas supplier 163. The carbon-containing gas is not limited to acetylene. For example, any of an ethylene (C₂H₄) gas, a methane (CH₄) gas, an ethane (C₂H₆) gas, a propane (C₃H₈) gas, a propylene (C₃H₆) gas, a methanol (CH₃OH) gas, and an ethanol (C₂H₅OH) gas may be used.

### Evaluation of Plasma Ignition Sequence

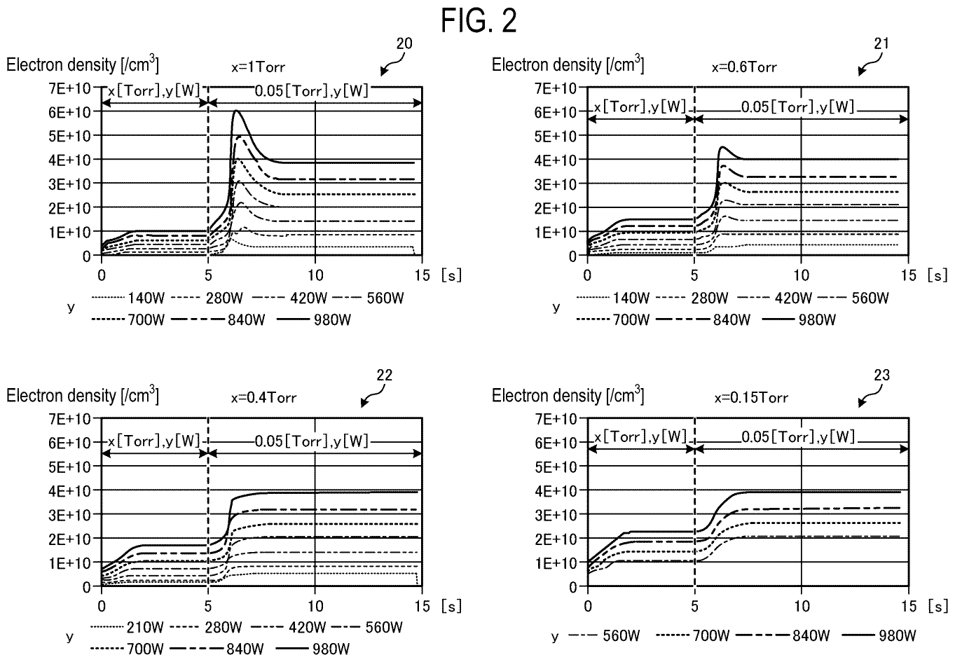

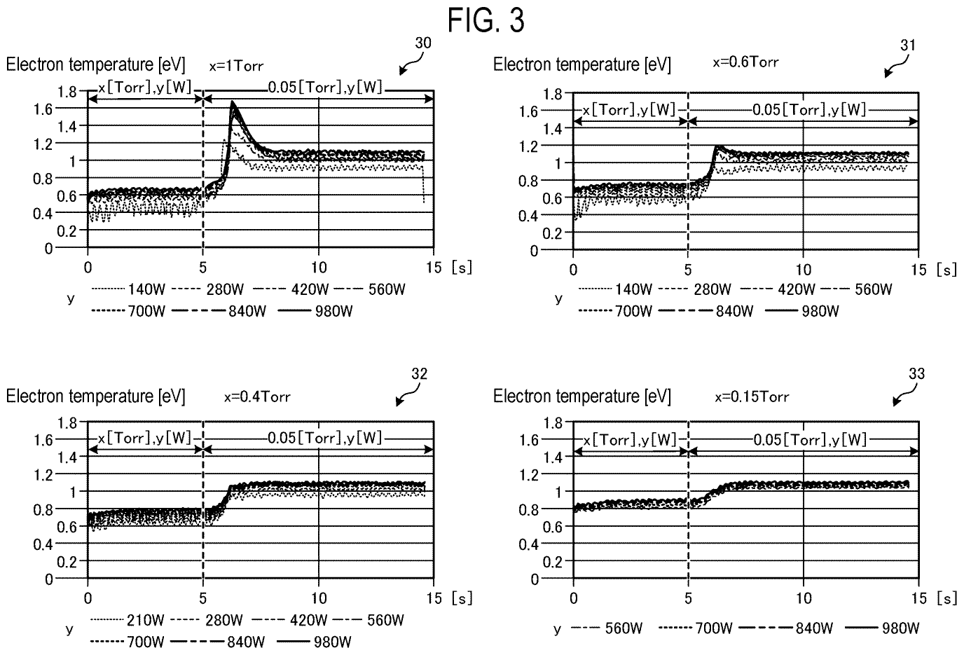

Next, evaluation of electron density and electron temperature when conditions are changed in the sequence of plasma ignition and pressure control (hereinafter also simply referred to as plasma ignition sequence) will be described with reference to FIGS. 2 and 3. FIG. 2 are graphs showing examples of changes in electron density during plasma ignition and pressure control. Graphs 20 to 23 shown in FIG. 2 show the time progression of electron density for each microwave power y, with pressure x at plasma ignition and microwave power y.

The graph 20 shows a change in electron density when the pressure x at plasma ignition is 1 Torr and the microwave power y is 140 W, 280 W, 420 W, 560 W, 700 W, 840 W, and 980 W. In the graph 20, 5 seconds after plasma ignition, the pressure is reduced from 1 Torr to 0.05 Torr at which film formation is performed. Note that the microwave power is constant before and after the pressure change. In the graph 20, it can be seen that the peak of the electron density occurs as the pressure changes from the pressure at plasma ignition to the pressure at which film formation is performed. In addition, the higher the microwave power, the larger the electron density peak.

The graph 21 shows a change in electron density when the pressure x at plasma ignition is 0.6 Torr and the microwave power y is 140 W, 280 W, 420 W, 560 W, 700 W, 840 W, and 980 W. In the graph 21, 5 seconds after plasma ignition, the pressure is reduced from 0.6 Torr to 0.05 Torr at which film formation is performed. Note that the microwave power is constant before and after the pressure change. In the graph 21, it can be seen that the electron density peak, although it is lower than that in the graph 20, occurs as the pressure changes from the pressure at plasma ignition to the pressure at which film formation is performed. In addition, the electron density peak becomes larger as the microwave power becomes higher, but there is almost no electron density peak when the microwave power is 140 W and 280 W.

The graph 22 shows a change in electron density when the pressure x at plasma ignition is 0.4 Torr and the microwave power y is 210 W, 280 W, 420 W, 560 W, 700 W, 840 W, and 980 W. In the graph 22, 5 seconds after plasma ignition, the pressure is reduced from 0.4 Torr to 0.05 Torr at which film formation is performed. Note that the microwave power is constant before and after the pressure change. In the graph 22, the electron density increases with the change from the pressure at plasma ignition to the pressure at which film formation is performed, but does not have a peak. In addition, the higher the microwave power, the steeper the rise angle of the electron density.

The graph 23 shows a change in electron density when the pressure x at plasma ignition is 0.15 Torr and the microwave power y is 560 W, 700 W, 840 W, and 980 W. In the graph 23, 5seconds after plasma ignition, the pressure is reduced from 0.15 Torr to 0.05 Torr at which film formation is performed. Note that the microwave power is constant before and after the pressure change. In the graph 23, the electron density increases with the change from the pressure at plasma ignition to the pressure at which film formation is performed, but does not have a peak. In addition, the rise angle of the electron density is gentler than that of the graph 22.

FIG. 3 are graphs showing examples of changes in electron temperature during plasma ignition and pressure control. Graphs 30 to 33 shown in FIG. 3 show the time progression of the electron temperature for each microwave power y, with pressure x at plasma ignition and microwave power y.

The graph 30 shows a change in electron temperature when the pressure x at plasma ignition is 1 Torr and the microwave power y is 140 W, 280 W, 420 W, 560 W, 700 W, 840 W, and 980 W. In the graph 30, 5 seconds after plasma ignition, the pressure is reduced from 1 Torr to 0.05 Torr at which film formation is performed. Note that the microwave power is constant before and after the pressure change. In the graph 30, it can be seen that the peak of the electron temperature occurs as the pressure changes from the pressure at plasma ignition to the pressure at which film formation is performed. In addition, the higher the microwave power, the larger the electron temperature peak.

The graph 31 shows a change in electron temperature when the pressure x at plasma ignition is 0.6 Torr and the microwave power y is 140 W, 280 W, 420 W, 560 W, 700 W, 840 W, and 980 W. In the graph 31, 5 seconds after plasma ignition, the pressure is reduced from 0.6 Torr to 0.05 Torr at which film formation is performed. Note that the microwave power is constant before and after the pressure change. In the graph 31, it can be seen that the electron temperature peak, although it is lower than that in the graph 30, occurs as the pressure changes from the pressure at plasma ignition to the pressure at which film formation is performed. In addition, when the microwave power is 140 W, there is no peak in the electron temperature, and when the microwave power is 280 W to 980 W, there is a peak in the electron temperature, although a difference between the respective peaks is small.

The graph 32 shows a change in electron temperature when the pressure x at plasma ignition is 0.4 Torr and the microwave power y is 210 W, 280 W, 420 W, 560 W, 700 W, 840 W, and 980 W. In the graph 32, 5 seconds after plasma ignition, the pressure is reduced from 0.4 Torr to 0.05 Torr at which film formation is performed. Note that the microwave power is constant before and after the pressure change. In the graph 32, the electron temperature rises with the change from the pressure at plasma ignition to the pressure at which film formation is performed, but does not have a peak. In addition, the higher the microwave power, the steeper the rise angle the electron temperature, although a difference in the electron temperature is smaller as compared to the electron density.

The graph 33 shows a change in electron temperature when the pressure x at plasma ignition is 0.15 Torr and the microwave power y is 560 W, 700 W, 840 W, and 980 W. In the graph 33, 5 seconds after plasma ignition, the pressure is reduced from 0.15 Torr to 0.05 Torr at which film formation is performed. Note that the microwave power is constant before and after the pressure change. In the graph 33, the electron temperature rises with the change from the pressure at plasma ignition to the pressure at which film formation is performed, but does not have a peak. In addition, the rise angle of the electron temperature during the rise is gentler than that in the graph 32.

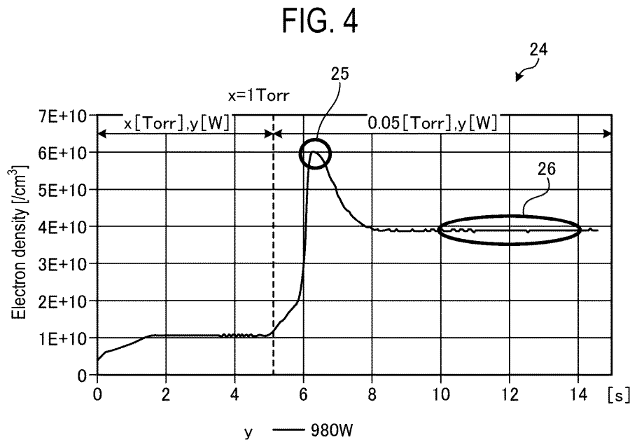

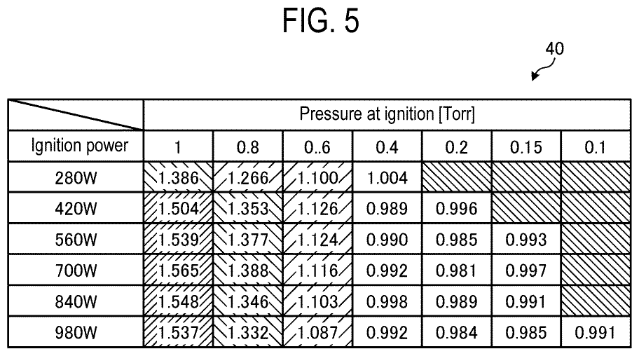

Subsequently, an evaluating method of the graphs 20 to 23 and 30 to 33 will be described with reference to FIGS. 4 and 5. FIG. 4 is a diagram showing an example of a peak evaluating method in an electron density graph. A graph 24 shown in FIG. 4 is an electron density graph for the microwave power of 980 W, which is extracted from the graph 20. In the evaluation of changes in electron density and electron temperature, first, as shown in the graph 24, the maximum value immediately after the pressure change, for example, during the period of 5 to 7 seconds after plasma ignition, is set as a peak value 25, and the average value after the pressure is stabilized, for example, during the period of 10 to 14 seconds after plasma ignition, is set as a plateau value 26. Next, a value obtained by dividing the peak value 25 by the plateau value 26 is set as an evaluation value for evaluating the height of the peak.

FIG. 5 is a diagram showing an example of the evaluation value of the electron temperature for combinations of supply power and pressure at plasma ignition. A table 40 shown in FIG. 5 shows an evaluation value of the electron temperature for each combination of the microwave power (represented as ignition power in the table 40) and pressure at plasma ignition. As shown in the table 40, it can be seen that the evaluation value is less than 1, that is, no peak occurs, in case of low-pressure and high-power plasma ignition. That is, it implies that the low-pressure and high-power plasma ignition can suppress the fluctuation of the plasma state during pressure changes. From this point, by performing the low-pressure and high-power plasma ignition and then transitioning to a pressure at which film formation is performed, it is possible to suppress the generation of unexpected particles due to the transient state during plasma ignition. In other words, it is possible to suppress the electron temperature spike (the electron temperature peak) during plasma ignition, which results in reduction of damage to the inner wall of the chamber 101, leading to the suppression of particle generation sources and the suppression of generation of unexpected particles.

### Evaluation of Pressure Control Method and Carbon-Containing Gas Supply Method

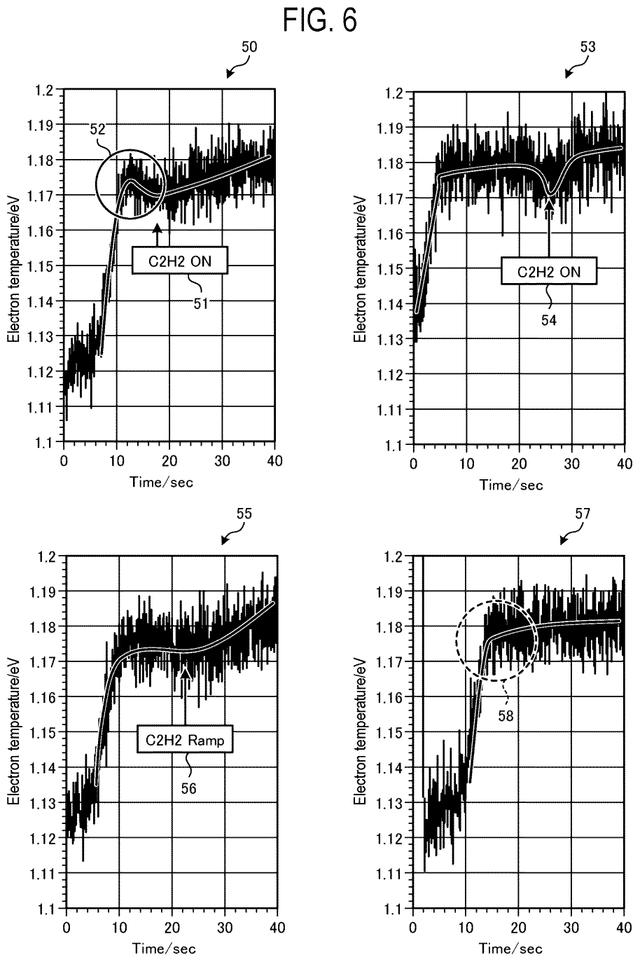

Next, the evaluation of the pressure control method and the carbon-containing gas supply method will be described with reference to FIG. 6. FIG. 6 are diagrams showing examples of evaluating the pressure control method and the carbon-containing gas supply method. Note that in graphs 50, 53, 55, and 57 shown in FIG. 6, the pressure at plasma ignition is set to 60 mTorr, and ramp down control is performed which decreases the pressure to 50 mTorr over 5 seconds after plasma ignition.

The graph 50 shows a change in electron temperature when a C₂H₂ gas is started to be supplied as a carbon-containing gas without ramping up at timing 51, about 17 seconds after plasma ignition. In the graph 50, a small peak 52 occurs at the point of time when pressure ramp control is completed.

The graph 53 shows a change in electron temperature when the pressure is maintained at 50 mTorr for 15 seconds after the pressure ramp control is completed after plasma ignition, and then the supply of C₂H₂ gas is started. In the graph 53, the C₂H₂ gas is started to be supplied as a carbon-containing gas without ramping up at timing 54, about 26 seconds after plasma ignition. In the graph 53, no peak of the electron temperature occurs at the point of time when pressure ramp control is completed, and a temporary drop of the electron temperature is observed at timing 54 when the supply of C₂H₂ gas is started.

The graph 55 shows a change in electron temperature when the pressure is maintained at 50 mTorr for 5 seconds after the pressure ramp control is completed after plasma ignition, and then the supply of C₂H₂ gas is started with ramping up control. In the graph 55, the C₂H₂ gas is started to be supplied as a carbon-containing gas with ramping up control at timing 56, about 23 seconds after plasma ignition. In the graph 55, no peak of the electron temperature occurs at the point of time when the pressure ramp control is completed. In addition, in the graph 55, a temporary drop of the electron temperature at timing 56 when the supply of C₂H₂ gas is started is gentler than in the graph 53 and is almost flat.

The graph 57 shows, for comparison, a change in electron temperature when no C₂H₂ gas is supplied after the pressure ramp control is completed after plasma ignition. In the graph 57, no peak of the electron temperature occurs in a rising portion 58 of the graph where the pressure ramp control is completed. From the graph 57, it can be seen that when no C₂H₂ gas is supplied, a peak such as that shown in the peak 52 does not occur in a rising portion of the electron temperature (the rising portion 58), and no increase in the electron temperature is observed thereafter. In addition, from a comparison of the graphs 50 and 53 with the graph 57, it can be seen that the temporary drop of the electron temperature is caused by the supply of C₂H₂ gas. In addition, from the graph 55, it can be seen that the change in the electron temperature can be made gentle by supplying the C₂H₂ gas with ramping up control after maintaining the pressure for a certain period of time. In other words, a gentle change in the electron temperature means that the fluctuation in the state of the plasma can be suppressed. Therefore, as in the condition of the graph 55, after plasma ignition, the pressure is ramped down and maintained for a certain period of time, and then the C₂H₂ gas is ramped up and supplied, thereby suppressing the generation of unexpected particles due to the transient state at plasma ignition.

### Film Forming Method

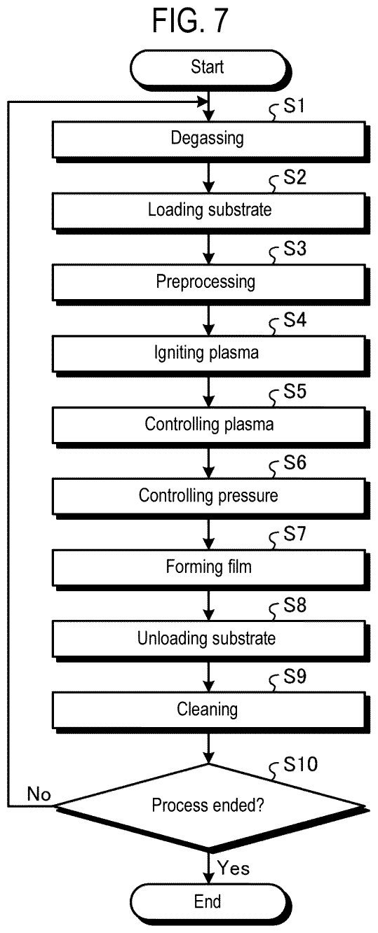

Subsequently, a film forming method according to this embodiment will be described. FIG. 7 is a flowchart showing an example of a film forming process according to this embodiment.

In the film forming process according to this embodiment, first, the controller 11 performs a degassing process of removing residual oxygen in a state in which the inside of the chamber 101 is cleaned (step S1). The controller 11 controls the gate valve 118 to open the opening 117. When the opening 117 is opened, a dummy wafer is loaded into a processing space of the chamber 101 through the opening 117 and is placed on the stage 102. The controller 11 controls the gate valve 118 to close the opening 117.

The controller 11 controls the gas supplier 163 to supply a hydrogen- or nitrogen-containing gas from the plurality of discharge ports 167 into the chamber 101. The controller 11 also controls the exhauster 105 to control the internal pressure of the chamber 101 to a predetermined pressure (for example, 50 mTorr to 1 Torr). For example, a H₂ gas, a N₂ gas, a mixed gas of these, or a mixed gas of these and an Ar gas can be used as the hydrogen- or nitrogen-containing gas in the degassing step. The controller 11 controls the microwave introducer 103 to ignite the plasma. The controller 11 executes the degassing step with the plasma of the hydrogen-containing gas for a predetermined time (for example, 120 seconds to 180 seconds). In the degassing step, oxidizing components such as O₂ and H₂O remaining in the chamber 101 are discharged as O-containing radicals. A dummy wafer may not be used in the degassing step. In addition, the degassing step may be omitted.

When the degassing step is completed, the controller 11 controls the gate valve 118 to open the opening 117. When the opening 117 is opened, the substrate W is loaded into the processing space of the chamber 101 through the opening 117 and is placed on the stage 102. That is, the controller 11 controls the apparatus body 10 to load the substrate W into the chamber 101 (step S2). The controller 11 controls the gate valve 118 to close the opening 117.

The controller 11 controls the exhauster 105 to reduce the internal pressure of the chamber 101 to a predetermined pressure (for example, 50 mTorr to 1 Torr). The predetermined pressure is an example of a third pressure. The controller 11 controls the gas supplier 163 to supply a hydrogen-containing gas and a carbon-containing gas, which are plasma generating gases, into the chamber 101 from the discharge ports 167. The hydrogen-containing gas is a gas containing a hydrogen (H₂) gas and an inert gas (Ar gas). The carbon-containing gas is a gas containing a hydrocarbon gas (e.g., a C₂H₂ gas) represented by CₓH_{y} (x and y are natural numbers). In addition, the controller 11 controls the microwave introducer 103 to ignite the plasma with a microwave of predetermined power (e.g., 100 W to 1,500 W). The predetermined power is an example of third power. The controller 11 executes a preprocessing step for improving various characteristics of the surface of the substrate W with plasma of the hydrogen-containing gas and the carbon-containing gas for a predetermined time (e.g., 5 seconds to 15 minutes) (step S3). For example, in the preprocessing step, the adhesion between the surface of the substrate W and the graphene film is improved.

The plasma generating gas may be one or more of a H₂ gas, a CₓH_{y} gas, and an Ar gas. In addition, in the preprocessing step, even when the CₓH_{y} gas is supplied, graphene film formation is not performed. Furthermore, in the preprocessing step, an annealing process may be performed in addition to or instead of the plasma process. When the annealing process is performed, the internal pressure of the chamber 101 is reduced to a predetermined pressure (e.g., 50 mTorr to 1 Torr), and, for example, a hydrogen-containing gas is supplied into the chamber 101. The predetermined pressure is an example of a fourth pressure. In addition, the preprocessing step may be omitted.

When the preprocessing step is completed, the controller 11 stops the microwave to stop the generation of plasma. The controller 11 controls the exhauster 105 to reduce the internal pressure of the chamber 101 to a first pressure (e.g., 50 mTorr to 200 mTorr). The first pressure is preferably in a range of 50 mTorr to 100 mTorr, more preferably in a range of 50 mTorr to 70 mTorr. The controller 11 controls the gas supplier 163 to supply an inert gas (Ar gas), which is a plasma generating gas, into the chamber 101 from the discharge ports 167. The plasma generating gas may contain a H₂ gas as a hydrogen-containing gas. The controller 11 also controls the microwave introducer 103 to execute a plasma igniting process of igniting plasma with first power (e.g., 1,900 W to 3,100 W) (step S4).

While maintaining the first pressure after the plasma is ignited, the controller 11 controls the microwave introducer 103 to execute a plasma controlling process of generating plasma with second power (e.g., 100 W to 1,500 W) lower than the first power (step S5). Note that in the plasma controlling step, while maintaining the plasma ignited with the first power, the power of the supplied microwave is reduced to transition from the plasma with the first power to the plasma with the second power. In addition, the plasma controlling step may be omitted.

When the plasma controlling step is completed, the controller 11 controls the exhauster 105 to execute a pressure controlling process of reducing the internal pressure of the chamber 101 to a second pressure (e.g., 10 mTorr to 50 mTorr) lower than the first pressure (step S6). The second pressure is preferably in a range of 30 mTorr to 50 mTorr, more preferably in a range of 40 mTorr to 50 mTorr. At this time, the controller 11 may control the internal pressure of the chamber 101 to be reduced from the first pressure to the second pressure by performing ramp-down control. In addition, the controller 11 may control the pressure controlling step to maintain the second pressure for a first period of time (e.g., 5 seconds to 20 seconds) after reducing the pressure to the second pressure.

When the pressure controlling step is completed, the controller 11 controls the gas supplier 163 to supply a carbon-containing gas into the chamber 101 from the discharge ports 167. The carbon-containing gas is, for example, a C₂H₂ gas. At this time, the controller 11 may control the gas supplier 163 to perform ramp-up control for the carbon-containing gas to reach a set flow rate. That is, the controller 11 controls the gas supplier 163 to supply the carbon-containing gas by gradually increasing the flow rate of the carbon-containing gas to reach the set flow rate during a second period of time (e.g., 5 seconds to 20 seconds). The controller 11 executes a film-forming process of forming a graphene film on the substrate W with plasma of an inert gas and a carbon-containing gas for a predetermined time (e.g., 5 seconds to 15 minutes) (step S7). Note that a hydrogen-containing gas may be also contained in the plasma generating gas in the film-forming step.

When the film-forming step is completed, the controller 11 stops the microwave to stop the generation of plasma. The controller 11 also controls the gate valve 118 to open the opening 117. The controller 11 controls the apparatus body 10 to lift the substrate W by causing substrate support pins (not shown) to protrude from the upper surface of the stage 102. When the opening 117 is opened, the substrate W is unloaded from the chamber 101 by an arm of a transfer chamber (not shown) through the opening 117. That is, the controller 11 controls the apparatus body 10 to unload the substrate W from the chamber 101 (step S8).

After the substrate W is unloaded, the controller 11 executes a cleaning process of cleaning the inside of the chamber 101 (step S9). In the cleaning step, a dummy wafer is placed on the stage 102 and a cleaning gas is supplied into the chamber 101 to clean a carbon film such as an amorphous carbon film attached to the inner wall of the chamber 101. Note that although an O₂ gas can be used as the cleaning gas, a gas containing oxygen, such as a CO gas or a CO₂ gas, may also be used. In addition, the cleaning gas may also contain a rare gas such as an Ar gas. In addition, the dummy wafer may not be used. Note that the cleaning step may be performed for each film-forming step for a plurality of substrates W.

When the cleaning step is completed, the controller 11 determines whether or not to end the film forming process (step S10). When it is determined not to end the film forming process (NO in step S10), the controller 11 returns to step S1, places the next substrate W, and executes the preprocessing step, the plasma igniting step, the plasma controlling step, the pressure controlling step, the film-forming step, and the cleaning step. On the other hand, when it is determined to end the film forming process (YES in step S10), the controller 11 ends the film forming process. In this way, by controlling the microwave power at plasma ignition and the internal pressure of the chamber 101, it is possible to suppress the generation of particles that occur unexpectedly.

### Experimental Results

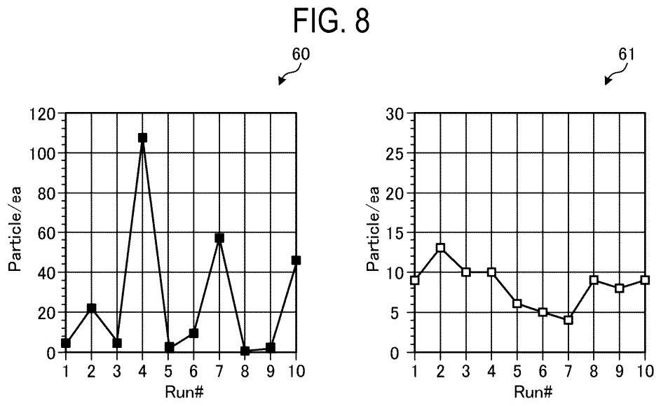

Next, the experimental results of this embodiment will be described with reference to FIG. 8. FIG. 8 are diagrams showing examples of the experimental results of a reference example and this embodiment, respectively. A graph 60 shown in FIG. 8 shows the results of the number of particles in the reference example. In the graph 60, the number of processed substrates W is 10, the horizontal axis represents the film forming process of each substrate W by Run #, and the vertical axis represents the number of particles. In the reference example of the graph 60, plasma is ignited under the conditions where the internal pressure of the chamber 101 is 400 mTorr and the microwave power is 1,400 W, and the pressure is reduced to 50 mTorr and then the supply of C₂H₂ gas is started to perform a film-forming step. In this case, for example, in Run #4, the number of particles unexpectedly exceeds 100. It is presumed that the increase in the number of unexpected particles in the reference example occurs due to a change in the plasma state of the inside of the discharge ports 167 (gas nozzle) that supply a plasma generating gas when the internal pressure of the chamber 101 is reduced after plasma ignition.

A graph 61 shown in FIG. 8 shows the results of the number of particles in an experimental example according to this embodiment. In the graph 61, the number of processed substrates W is 10, the horizontal axis represents the film forming process of each substrate W by Run #, and the vertical axis represents the number of particles. In the experimental example of the graph 61, plasma is ignited under the conditions where the internal pressure of the chamber 101 is 60 mTorr and the microwave power is 2,450 W, and then the microwave power is reduced to 1,400 W. After that, ramping-down control to reduce the internal pressure of the chamber 101 from 60 mTorr to 50 mTorr is performed, and then the supply of C₂H₂ gas is started to perform a film-forming step. In this case, in Runs #1 to #10, the number of particles is 15 or less and it can be seen that the generation of particles that occur unexpectedly can be suppressed.

As described above, according to this embodiment, the substrate processing apparatus (the film forming apparatus 1) includes the process container (the chamber 101) capable of accommodating the substrate W, and the controller 11. The controller 11 executes the process of placing the substrate W on the mounting table (the stage 102) in the process container, the process of supplying a plasma generating gas into the process container to generate plasma of the first power at the first pressure, the process of controlling the inside of the process container to the second pressure lower than the first pressure, and the process of supplying a carbon-containing gas into the process container to form a graphene film on the substrate W. As a result, it is possible to suppress the generation of particles that occur unexpectedly.

In addition, according to this embodiment, after the process of generating plasma of the first power, the controller 11 further executes the process of generating plasma of the second power lower than the first power while maintaining the first pressure. As a result, it is possible to generate plasma with power suitable for graphene film formation.

In addition, according to this embodiment, after the process of controlling the inside of the process container to the second pressure, the controller 11 further executes the process of maintaining the second pressure for the first period of time. As a result, it is possible to suppress the fluctuation of the plasma state.

In addition, according to this embodiment, the carbon-containing gas is supplied at a stepwise increased rate so as to reach a set flow rate during the second period of time. As a result, it is possible to suppress the fluctuation of the plasma state.

In addition, according to this embodiment, the first pressure is in the range of 50 mTorr to 200 mTorr. As a result, it is possible to easily ignite the plasma.

In addition, according to this embodiment, the second pressure is in the range of 10 mTorr to 50 mTorr. As a result, it is possible to set the pressure to be suitable for graphene film formation.

In addition, according to this embodiment, the first power is in the range of 1,900 W to 3,100 W. As a result, it is possible to easily ignite the plasma.

In addition, according to this embodiment, the second power is in the range of 100 W to 1,500 W. As a result, it is possible to generate plasma of power suitable for graphene film formation.

In addition, according to this embodiment, the first period of time is in the range of 5 seconds to 20 seconds. As a result, it is possible to suppress the fluctuation of the plasma state.

In addition, according to this embodiment, the second period of time is in the range of 5 seconds to 20 seconds. As a result, it is possible to suppress the fluctuation of the plasma state.

In addition, according to this embodiment, the plasma generating gas includes at least one of an Ar gas and a H₂ gas. As a result, it is possible to generate plasma suitable for graphene film formation.

In addition, according to this embodiment, the carbon-containing gas includes at least one of a C₂H₂ gas, a C₂H₄ gas, a CH₄ gas, a C₂H₆ gas, a C₃H₆ gas, a C₃H₆ gas, a CH₃OH gas, and a C₂H₅OH gas. As a result, it is possible to form a graphene film on the substrate W.

In addition, according to this embodiment, before the process of generating plasma of the first power, the controller 11 further executes the process of supplying at least Ar gas and H₂ gas and generating plasma of the third power at the third pressure to preprocess the substrate W. As a result, it is possible to form a graphene film after improving various characteristics of the surface of the substrate W.

In addition, according to this embodiment, before the process of generating plasma of the first power, the controller 11 further executes the process of supplying at least Ar gas and H₂ gas to preprocess the substrate W without generating plasma at the fourth pressure. As a result, it is possible to form a graphene film after improving various characteristics of the surface of the substrate W.

In addition, according to this embodiment, the third pressure is in the range of 50 mTorr to 1 Torr. As a result, it is possible to set the pressure to be suitable for preprocessing the substrate W.

In addition, according to this embodiment, the third power is in the range of 100 W to 1,500 W. As a result, it is possible to generate plasma of power suitable for preprocessing the substrate W.

In addition, according to this embodiment, the fourth pressure is in the range of 50 mTorr to 1 Torr. As a result, it is possible to set the pressure to be suitable for preprocessing the substrate W.

According to the present disclosure in some embodiments, it is possible to suppress the generation of particles that occur unexpectedly.

It should be considered that the embodiment disclosed this time are illustrative in all respects and not restrictive. The above embodiment may be omitted, substituted, or modified in various ways without departing from the appended claims and the gist thereof.

In addition, in the above-described embodiment, the film forming apparatus 1 that performs processes such as etching and film formation for the substrate W using the microwave plasma as a plasma source has been described as an example, but the disclosed technique is not limited thereto. As long as an apparatus performs a process for the substrate W using plasma, a plasma source is not limited to microwave plasma, and may be any plasma sources such as capacitively-coupled plasma, inductively-coupled plasma, and magnetron plasma.

The present disclosure can also take the following configurations.
(1) A method of processing a substrate, including:
a process of placing the substrate on a stage in a process container;
a process of supplying a plasma generating gas into the process container to generate plasma of first power at a first pressure;
a process of controlling an inside of the process container to a second pressure lower than the first pressure; and
a process of supplying a carbon-containing gas into the process container to form a graphene film on the substrate.
(2) The method of (1), further including: after the process of generating plasma of the first power, a process of generating plasma of second power lower than the first power while maintaining the first pressure.
(3) The method of (1) or (2), further including: after the process of controlling the inside of the process container to the second pressure, a process of maintaining the second pressure for a first period of time.
(4) The method of any one of (1) to (3), wherein the carbon-containing gas is supplied at a stepwise increased flow rate during a second period of time to reach a set flow rate.
(5) The method of any one of (1) to (4), wherein the first pressure is in a range of 50 mTorr to 200 mTorr.
(6) The method of any one of (1) to (5), wherein the second pressure is in a range of 10 mTorr to 50 mTorr.
(7) The method of any one of (1) to (6), wherein the first power is in a range of 1,900 W to 3,100 W.
(8) The method of (2), wherein the second power is in a range of 100 W to 1,500 W.
(9) The method of (3), wherein the first period of time is in a range of 5 seconds to 20seconds.
(10) The method of (4), wherein the second period of time is in a range of 5 seconds to 20 seconds.
(11) The method of any one of (1) to (10), wherein the plasma generating gas includes at least one of an Ar gas and a H2 gas.
(12) The method of any one of (1) to (11), wherein the carbon-containing gas includes at least one of a C2H2 gas, a C₂H₄ gas, a CH₄ gas, and a C₂H₆ gas.
(13) The method of any one of (1) to (12), further including: before the process of generating the plasma of the first power, a process of supplying at least Ar gas and H2 gas and generating plasma of third power at a third pressure to preprocess the substrate.
(14) The method of any one of (1) to (13), further including: before the process of generating the plasma of the first power, a process of supplying at least Ar gas and H2 gas to preprocess the substrate without generating plasma at a fourth pressure.
(15) The method of (13), wherein the third pressure is in a range of 50 mTorr to 1 Torr.
(16) The method of (13), wherein the third power is in a range of 100 W to 1,500 W.
(17) The method of (14), wherein the fourth pressure is in a range of 50 mTorr to 1 Torr.
(18) A substrate processing apparatus including:
a process container capable of accommodating a substrate; and
a controller,
wherein the controller is configured to:
control the substrate processing apparatus to place the substrate on a stage in the process container;
control the substrate processing apparatus to supply a plasma generating gas into the process container to generate plasma of first power at a first pressure;
control the substrate processing apparatus to control an inside of the process container to a second pressure lower than the first pressure; and
control the substrate processing apparatus to supply a carbon-containing gas into the process container to form a graphene film on the substrate.

What is claimed is:

1. A method of processing a substrate, comprising:
placing the substrate on a stage in a process container;
supplying a plasma generating gas into the process container to generate plasma of first power at a first pressure;
controlling an inside of the process container to a second pressure lower than the first pressure; and
supplying a carbon-containing gas into the process container to form a graphene film on the substrate.

2. The method of claim 1, further comprising: after the process of generating plasma of the first power, generating plasma of second power lower than the first power while maintaining the first pressure.

3. The method of claim 1, further comprising: after the process of controlling the inside of the process container to the second pressure, maintaining the second pressure for a first period of time.

4. The method of claim 1, wherein the carbon-containing gas is supplied at a stepwise increased flow rate during a second period of time to reach a set flow rate.

5. The method of claim 1, wherein the first pressure is in a range of 50 mTorr to 200 mTorr.

6. The method of claim 1, wherein the second pressure is in a range of 10 mTorr to 50 mTorr.

7. The method of claim 1, wherein the first power is in a range of 1,900 W to 3,100 W.

8. The method of claim 2, wherein the second power is in a range of 100 W to 1,500 W.

9. The method of claim 3, wherein the first period of time is in a range of 5 seconds to 20 seconds.

10. The method of claim 4, wherein the second period of time is in a range of 5 seconds to 20 seconds.

11. The method of claim 1, wherein the plasma generating gas includes at least one of an Ar gas and a H₂ gas.

12. The method of claim 1, wherein the carbon-containing gas includes at least one of a C₂H₂ gas, a C₂H₄ gas, a CH₄ gas, a C₂H₆ gas, a C₃H₈ gas, a C₃H₆ gas, a CH₃OH gas, and a C₂H₅H gas.

13. The method of claim 1, further comprising: before the process of generating the plasma of the first power, supplying at least Ar gas and H₂ gas and generating plasma of third power at a third pressure to preprocess the substrate.

14. The method of claim 1, further comprising: before the process of generating the plasma of the first power, a process of supplying at least Ar gas and H₂ gas to preprocess the substrate without generating plasma at a fourth pressure.

15. The method of claim 13, wherein the third pressure is in a range of 50 mTorr to 1 Torr.

16. The method of claim 13, wherein the third power is in a range of 100 W to 1,500 W.

17. The method of claim 14, wherein the fourth pressure is in a range of 50 mTorr to 1 Torr.

18. A substrate processing apparatus comprising:
a process container capable of accommodating a substrate; and
a controller,
wherein the controller is configured to:
control the substrate processing apparatus to place the substrate on a stage in the process container;
control the substrate processing apparatus to supply a plasma generating gas into the process container to generate plasma of first power at a first pressure;
control the substrate processing apparatus to control an inside of the process container to a second pressure lower than the first pressure; and
control the substrate processing apparatus to supply a carbon-containing gas into the process container to form a graphene film on the substrate.
